(19) United States
(12) Patent Application Publication
(10) Pub. No.: US 2026/0096075 A1
(43) Pub. Date: Apr. 2, 2026

(54) ELECTRONIC DEVICE

(71) Applicant: Advanced Semiconductor Engineering, Inc., Kaohsiung (TW)

(72) Inventors: Shao-En HSU, Kaohsiung (TW); Hsin-Yu CHEN, Kaohsiung (TW)

(73) Assignee: Advanced Semiconductor Engineering, Inc., Kaohsiung (TW)

(21) Appl. No.: 18/905,113

(22) Filed: Oct. 2, 2024

(51) Int. Cl. H05K 9/00; H05K 1/02; H05K 1/18

(52) U.S. Cl. CPC H05K 9/0024; H05K 1/0216; H05K 1/181; H05K 2201/10015

(57) ABSTRACT

An electronic device is provided. The electronic device includes a first circuit module and a first shield. The first shield is disposed at a lateral side of the circuit module and includes a first opening configured to reduce a parasitic coupling of the first circuit module and the first shield.

### BACKGROUND

### 1. Field of the Disclosure

The present disclosure relates to an electronic device.

### 2. Description of the Related Art

An EOS (electrical overstress) protection circuit may be covered by a lid or a shield to prevent electromagnetic interference from an external environment; however, there can be unwanted parasitic coupling between the EOS protection circuit and the lid.

### SUMMARY

In some embodiments, an electronic device includes a first circuit module and a first shield. The first shield is disposed at a lateral side of the circuit module and includes a first opening configured to reduce a parasitic coupling of the first circuit module and the first shield.

In some embodiments, an electronic device includes a circuit module and a shield. The circuit module includes a first passive component. The shield is disposed at a lateral surface of the circuit module. The shield includes an opening faced toward the first passive component.

In some embodiments, an electronic device includes a carrier, a circuit module, and a shield. The carrier has a long side. The circuit module is disposed over the carrier. The shield surrounds the circuit module and includes an opening. The electronic device has a Time Domain Reflectometry (TDR) characteristic. The TDR characteristic has a first turning point corresponding to a location of the opening with respect to the long side of the carrier.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a schematic diagram of an electronic device according to some embodiments of the present disclosure.

FIG. 2 is a schematic diagram of an electronic device according to some embodiments of the present disclosure.

FIG. 3 is a schematic diagram of an electronic device according to some embodiments of the present disclosure.

FIG. 4 is a cross-section of an electronic device according to some embodiments of the present disclosure.

FIG. 5 is a circuit diagram of a circuit module according to some embodiments of the present disclosure.

FIG. 6 is a top view of an electronic device according to some embodiments of the present disclosure.

FIG. 7 is a three-dimensional view of an electronic device according to some embodiments of the present disclosure.

FIG. 8 is a three-dimensional view of an electronic device according to some embodiments of the present disclosure.

FIG. 9 is a top view of an electronic device according to some embodiments of the present disclosure.

FIG. 10 is a plot for a near-end-cross-talk of terminals in an electronic device according to some embodiments of the present disclosure.

FIG. 11 is a Time Domain Reflectometry plot of an electronic device according to some embodiments of the present disclosure.

FIGS. 12A, 12B, and 12C each represent a circuit diagram of a circuit module according to some embodiments of the present disclosure.

FIGS. 13A, 13B, 13C, 13D, 13E, and 13F are three-dimensional views of an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

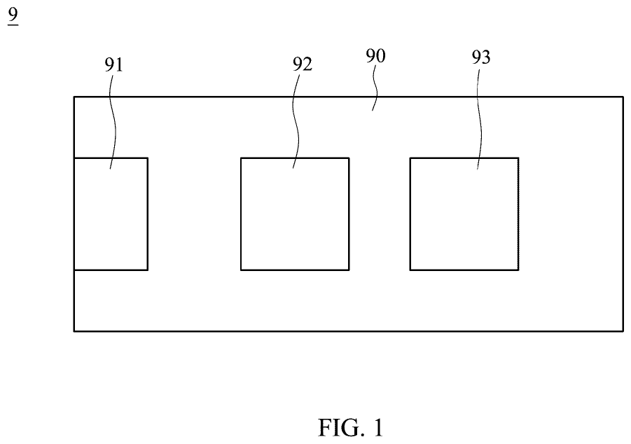

FIG. 1 is a schematic diagram of an electronic device 9 according to some embodiments of the present disclosure. The electronic device 9 may include a carrier 90, a connector 91, and a first protection circuit 92 including a plurality of passive components (e.g., a resistor and/or a capacitor). The first protection circuit 92 may be configured to prevent the damage of a semiconductor chip or component induced by electrical overstress (EOS). The electronic device 9 further includes a second protection circuit 93 (e.g., a diode) configured to prevent the damage of a semiconductor chip or device induced by electrostatic discharge (ESD). The first protection circuit 92 and the second protection circuit 93 collectively protect the semiconductor chip or component of the electronic device 9. The connector 91, the first protection circuit 92, and the second protection circuit 93 may be disposed over and electrically connected to the carrier 90.

The carrier 90 may be or include, for example, one or more of a printed circuit board, such as a paper-based copper foil laminate, a composite copper foil laminate, a polymer-impregnated glass-fiber-based copper foil laminate, and so on.

The connector 91 may include a port for connecting an external device, such as a mobile phone, a computer, a keyboard, a mouse, a printer, and/or a charger. The connector 91 may include a USB port.

The first protection circuit 92 and the second protection circuit 93 are discrete components. The first protection circuit 92 may be individually mounted on the carrier 90 and the second protection circuit 93 may be individually mounted on the carrier 90. The first protection circuit 92 is spaced apart from the Second protection circuit 93 by a predetermined distance, such that they do not overlap/influence each other during mounting. The first protection circuit 92 may electrically connect to the second protection circuit 93 through the carrier 90. The connector 91 may be configured to receive an electrical signal. In some cases, the electrical signal may carry an unexpectedly high voltage, creating an EOS (electrical overstress) event. The first protection circuit 92 and the second protection circuit 93 may together protect the electronic device 9 from the event.

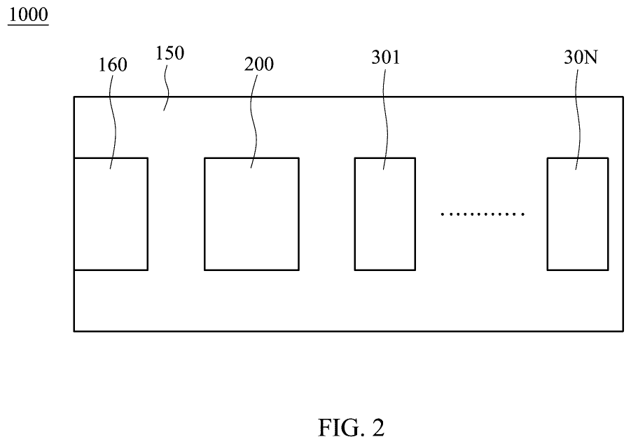

FIG. 2 is a schematic diagram of an electronic device (or an electronic system) 1000 according to some embodiments of the present disclosure. The electronic device (or the electronic system) 1000 may include a carrier 150, a connector 160, a semiconductor module 200, and a plurality of semiconductor dies 301, . . . , 30N, wherein N is a positive integer greater than 1. The connector 160, the semiconductor module 200, and the semiconductor dies 301, . . . , 30N may be disposed over and electrically connected to the carrier 150.

The carrier 150 may be or include, for example, one or more of a printed circuit board, such as a paper-based copper foil laminate, a composite copper foil laminate, a polymer-impregnated glass-fiber-based copper foil laminate, and so on.

The connector 160 may include a port for connecting an external device, such as a mobile phone, a computer, a keyboard, a mouse, a printer, and/or a charger. The connector 160 may include a USB port.

In some embodiments, the semiconductor dies 301, . . . , 30N may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the semiconductor dies 301, . . . , 30N may include one or more processing elements and one or more memory elements electrically connected to the processing elements. The processing element(s) and the memory element(s) may be divided from or originate in a monolithic processing unit (e.g., a CPU, a MPU, a GPU, an MCU, an ASIC, or the like). In some embodiments, the processing element may be a CPU chiplet, an MCU chiplet, a GPU chiplet, an ASIC chiplet, or the like. The memory element may be a cache memory.

The semiconductor module 200 may electrically connect to the connector 160. The semiconductor module 200 may electrically connect between the connector 160 and at least one of the semiconductor dies 301, . . . , 30N. The connector 160 may be configured to receive an electrical signal. In some cases, the electrical signal may carry an unexpectedly high voltage (i.e., an EOS event). The semiconductor module 200 may be configured to protect the semiconductor dies 301, . . . , 30N from EOS events.

The EOS events may result from the following cases: (1) interference between electrical sources, noise, or over-voltage; (2) transient current/peak/interference during a hot switching; (3) lightning; (4) glitch/pulse during a test; (5) a shabby circuit design; (6) interference from other equipment; (7) inadequate operating steps; and (8) an insufficient number of groundings.

In some cases, a protection circuit (e.g., 92) and a further protection circuit (e.g., 93) are discrete components individually mounted on a printed circuit board (e.g., 90). In FIG. 2, the semiconductor module 200 may include an integrated EOS protection circuit, which includes a passive component and an ESD protection diode. The passive component and the ESD protection diode are integrated into and additional carrier (e.g., redistribution layer structure) prior to being mounted on the carrier 150. The protection circuit (e.g., 92) and the further protection circuit (e.g., 93) are separated by a predetermined distance, while the semiconductor module 200 integrates the passive component and the ESD protection diode in advance. Therefore, the semiconductor module 200 may occupy a relatively smaller area over the carrier 150.

In some embodiments, the semiconductor module 200 may be configured to amplify the electrical signal from the connector 160. In some embodiments, the semiconductor module 200 may be configured to clamp the electrical signal from the connector 160. In some embodiments, the semiconductor module 200 may be configured to provide a clock signal to the semiconductor dies 301, . . . , 30N.

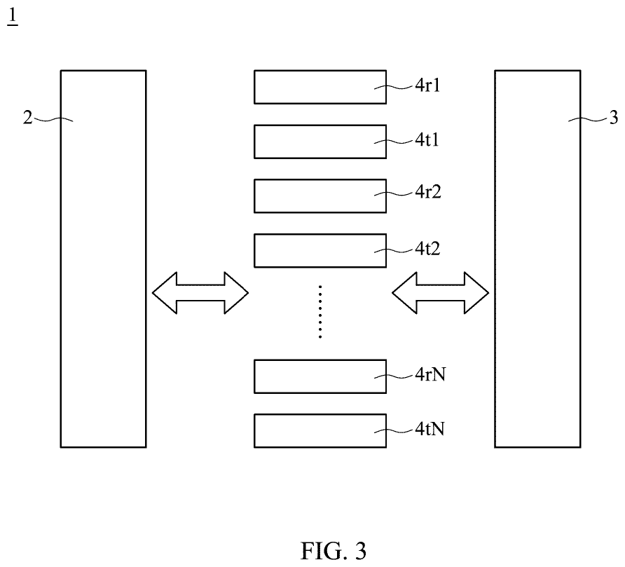

FIG. 3 is a schematic diagram of an electronic device (or an electronic system) 1 according to some embodiments of the present disclosure. The electronic device (or the electronic system) 1 may include a connector 2, a plurality of receivers 4r1, 4r2, . . . , 4rN, a plurality of transmitters 4t1, 4t2, . . . , 4tN, and an electronic component 3.

The connector 2 may include a port for connecting an external device, such as a mobile phone, a computer, a keyboard, a mouse, a printer, and/or a charger. The connector 2 may include a USB port.

The electronic component 3 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 3 may include one or more processing elements and one or more memory elements electrically connected to the processing elements. The processing element(s) and the memory element(s) may be divided from or originate in a monolithic processing unit (e.g., a CPU, a MPU, a GPU, an MCU, an ASIC, or the like). In some embodiments, the processing element may be a CPU chiplet, an MCU chiplet, a GPU chiplet, an ASIC chiplet, or the like. The memory element may be a cache memory.

In some embodiments, the electronic component 3 may include a re-timer configured to reshape and retime signals from the connector 2 to reduce jitter and other timing issues. In some embodiments, the re-timer may include a clock data recovery (CDR) circuit, a phase-locked loop (PLL), and a digital signal processing (DSP) circuit. These components work together to clean and reshape incoming signals from the connector 2 to improve overall signal integrity. The re-timer may provide a clock signal by receiving an input clock signal and using internal circuitry (e.g., CDR circuit) to clean up and regenerate the signal.

The receivers 4r1, 4r2, . . . , 4rN may be configured to receive electrical signals from the connector 2. The receivers 4r1, 4r2, . . . , 4rN may be responsible for a respective channel of the connector 2. The transmitters 4t1, 4t2, . . . , 4tN may be configured to transmit electrical signals to the connector 2. The transmitters 4t1, 4t2, . . . , 4tN may be responsible for a respective channel of the connector 2. The receivers 4r1, 4r2, . . . , 4rN and the transmitters 4t1, 4t2, . . . , 4tN may be arranged alternately in order, but this does not limit the scope of the present disclosure. In some embodiments, the arrangement of the receivers 4r1, 4r2, . . . , 4rN may be arranged in sequence and the arrangement of the transmitters 4t1, 4t2, . . . , 4tN may follow the receivers 4r1, 4r2, . . . , 4rN. In some embodiments, the arrangement of the transmitters 4t1, 4t2, . . . , 4tN may be arranged in sequence and the arrangement of the receivers 4r1, 4r2, . . . , 4rN may follow the transmitters 4t1, 4t2, . . . , 4tN.

Each of the transmitters 4t1, 4t2, . . . , 4tN and the receivers 4r1, 4r2, . . . , 4rN may include an EOS protection circuit to protect the electronic component 3 and/or an external electronic component connected to the connector 2.

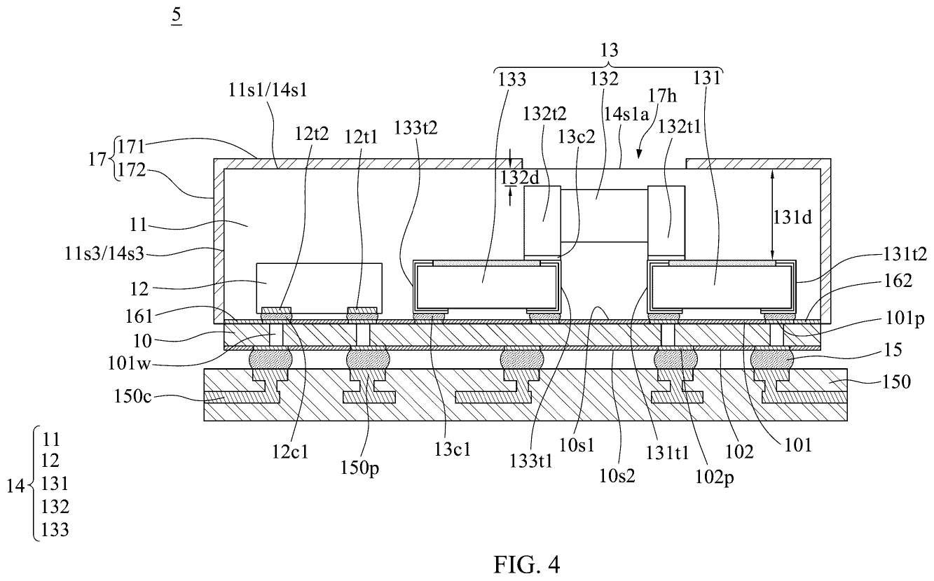

The receivers 4r1, 4r2, . . . , 4rN and the transmitters 4t1, 4t2, . . . , 4tN may be included in a semiconductor module (e.g., the semiconductor module 200 of FIG. 2) and a carrier (e.g., the carrier 150 of FIG. 2). Structural details of the receivers 4r1, 4r2, . . . , 4rN and the transmitters 4t1, 4t2, . . . , 4tN are provided in descriptions of FIGS. 4-9, and FIGS. 13A-13F.

The present disclosure provides an electronic device with a selective shielding structure to reduce the parasitic coupling (capacitance and/or inductance) between elements (e.g., a circuit module and a shield) of the electronic device. The selectively shielding structure includes an opening on the shield, which exposes a portion of the circuit module to reduce the parasitic coupling without significantly impacting the electromagnetic shielding of the shield. The opening may overlap a passive component of the circuit module. The location of the opening can be determined based on the types of the passive components, the distance between the passive component and the shield, and/or the volume of the passive component. Furthermore, the location of the opening can be determined by evaluating a turning point of the TDR characteristic of the electronic device, where a positive sign or negative sign of the slope of the TDR characteristic is changed. The turning point can correspond to the location of the opening of the shield with respect to the long side of a carrier (or a channel). The turning point can also correspond to the distance between the opening of the shield and a terminal of the channel.

FIG. 4 is a cross-section of an electronic device 5 according to some embodiments of the present disclosure. The electronic device 5 may be a part of the electronic device 1000 of FIG. 2. The cross-section of the electronic device 5 may be one of the cross-sections of the transmitters 4t1, 4t2, . . . , 4tN and the receivers 4r1, 4r2, . . . , 4rN.

The electronic device 5 may include a carrier 10, an encapsulation layer 11, a circuit module 14, and a shield 17. The electronic device 5 may be configured to protect an external electronic component (e.g., the semiconductor dies 301, . . . , 30N and the electronic component 3) from an EOS event, e.g., from a connector (e.g., the connector 160 or the connector 2).

In some embodiments, the electronic device 5 may be configured to amplify the electrical signal from a connector (e.g., the connector 160 or the connector 2). In some embodiments, the electronic device 5 may be configured to clamp the electrical signal from a connector (e.g., the connector 160 or the connector 2). In some embodiments, the electronic device 5 may be configured to provide a clock signal to an external electronic component (e.g., the semiconductor dies 301, . . . , 30N and the electronic component 3).

The carrier (or a circuit structure, a substrate) 10 may be or include, for example, one or more of a printed circuit board, such as a paper-based copper foil laminate, a composite copper foil laminate, a polymer-impregnated glass-fiber-based copper foil laminate, and so on. The carrier 10 may include a dielectric layer and an interconnection structure, such as a redistribution layer (RDL) and/or a grounding element.

The carrier 10 may have a surface (or a top surface) 10s1 and a surface (or a bottom surface) 10s2 opposite to the surface 10s1. The surface 10s1 may be covered and in contact with encapsulation layer 11. The surface 10s1 may face the electronic component 12, the passive components 13, and the encapsulation layer 11. The surface 10s2 may face away from the electronic component 12, the passive components 13, and the encapsulation layer 11.

The carrier 10 may include a protection layer 101 and a protection layer 102 opposite to the protection layer 101. The protection layer 101 may include a photoresist layer. The protection layer 102 may include a photoresist layer. The protection layer 101 may be disposed at the surface 10s1 of the carrier 10 and the protection layer 102 may be disposed at the surface 10s2 of the carrier 10. The carrier 10 may include a plurality of pads 101p disposed at the surface 10s1 of the carrier 10. The pads 101p may be enclosed by the protection layer 101. The pads 101p may electrically connect to the interconnection structure of the carrier 10. The carrier 10 may include a plurality of pads 102p disposed at the surface 10s2 of the carrier 10. The pads 102p may be enclosed by the protection layer 102. The pads 102p may electrically connect to the interconnection structure of the carrier 10. The carrier 10 may include a wiring structure 101w connected to the pads 101p and the pads 102p. The wiring structure 101w may include a conductive layer, a conductive via, or the like. The pads 101p may be metal, such as copper, gold, silver, aluminum, titanium, tantalum, or the like. The pads 102p may be metal, such as copper, gold, silver, aluminum, titanium, tantalum, or the like. The wiring structure 101w may be metal, such as copper, gold, silver, aluminum, titanium, tantalum, or the like.

The electronic device 5 may further include a plurality of connection elements 15 disposed below the carrier 10. The connection elements 15 may be connected to the pads 102p. The connection elements 15 may be mounted on the carrier 150. The carrier 10 may electrically connect to the carrier 150. The connection elements 15 may include solder balls, controlled collapse chip connection (C4) bumps, a ball grid array (BGA), or a land grid array (LGA).

The carrier 150 may include a plurality of conductive pads 150p connected to the connection elements 15. The carrier 150 may include a wiring structure 150c connected to the conductive pads 150p. The conductive pads 150p may be metal, such as copper, gold, silver, aluminum, titanium, tantalum, or the like. The wiring structure 150c may be metal, such as copper, gold, silver, aluminum, titanium, tantalum, or the like. The circuit module 14 may be electrically connected to the other elements (e.g., the connector 2, the electronic component 3, and/or the semiconductor die 301 to 30N in FIG. 2) via the carrier 150. The electronic device 5 may be configured to provide EOS protection for at least one semiconductor die (e.g., 301 to 30N in FIG. 2) on the carrier 150.

The circuit module 14 may be disposed over the carrier 10 (or the surface 10s1 of the carrier 10). The circuit module 14 may be supported by the carrier 10. The circuit module 14 may be electrically connected to the carrier 10. The circuit module 14 may be disposed over the carrier 150. The circuit module 14 may be supported by the carrier 150. The circuit module 14 may be electrically connected to the carrier 150. The circuit module 14 may include the encapsulation layer 11. The circuit module 14 may be (partially) surrounded by the shield 17.

The circuit module 14 may include an electronic component 12 and a plurality of passive components 131, 132, and 133. The electronic component 12 may be electrically connected to the passive component 133. The passive component 133 may be electrically connected to the passive component 132. The passive component 132 may be electrically connected to the passive component 131.

The electronic component 12 may be covered by the encapsulation layer 11. The electronic component 12 may be in contact with the encapsulation layer 11. The electronic component 12 may include a first terminal 12t1 and a second terminal 12t2. The first terminal 12t1 may be closer to the passive component 133 than the second terminal 12t2. The electronic device 5 may further include a plurality of connection elements 12c disposed over the surface 10s1 of the carrier 10. The connection elements 12c may be mounted on the pads 101p. The first terminal 12t1 and the second terminal 12t2 of the electronic component 12 may electrically connect to the carrier 10 through the connection elements 12c. The connection elements 12c may include solder balls, controlled collapse chip connection (C4) bumps, a ball grid array (BGA), or a land grid array (LGA).

In some embodiments, the electronic component 12 may include an ESD protection device. The electronic component 12 may include a voltage-clamping component. The electronic component 12 may include a diode. The electronic component 12 may include a Zener diode. The electronic component 12 may be configured to clamp a voltage of the electronic device 5. The electronic component 12 may be configured to provide a low impedance path in the electronic device 5.

The passive components 131, 132, and 133 may be covered by the encapsulation layer 11. The passive components 131, 132, and 133 may be in contact with the encapsulation layer 11. The semiconductor module 5 may further include a plurality of connection elements 13c1 disposed over the surface 10s1 of the carrier 10. The connection elements 13c1 may be mounted on the pads 101p. The passive components 131, 132, and 133 may electrically connect to the carrier 10 through the connection elements 13c1. The connection elements 13c1 may include solder balls, controlled collapse chip connection (C4) bumps, a ball grid array (BGA), or a land grid array (LGA).

The passive component 132 may be disposed over the passive component 131 in cross-section. The passive component 132 may be disposed over the passive component 133 in cross-section. The passive component 131 and the passive component 133 may be disposed below the passive component 132. The passive component 133 and the passive component 131 may be on the same horizontal plane. The passive component 132 and the passive component 131 may be on different horizontal planes. The passive component 132 and the passive component 133 may be on different horizontal planes. The passive component 132 may be higher than the passive components 131 and 133 with respect to the carrier 10.

The passive component 131 may include a first terminal 131t1 and a second terminal 131t2 connected to the connection elements 13c1. The passive component 133 may include a first terminal 133t1 and a second terminal 133t2 connected to the connection elements 13c1. The passive component 132 may include a first terminal 132t1 and a second terminal 132t2. The first terminal 132t1 of the passive component 132 may be connected to the first terminal 131t1 of the passive component 131. The first terminal 132t1 may be connected to the first terminal 131t1 through a connection element 13c2. The connection element 13c2 may include a solder bump or an electrically conductive adhesive layer. The connection element 13c1 may include material different from the connection element 13c2. In some embodiments, the connection element 13c1 may include the same material as the connection element 13c2. The second terminal 132t2 of the passive component 132 may be connected to the first terminal 133t1 of the passive component 133. The second terminal 132t2 may be connected to the first terminal 133t1 through the connection element 13c2.

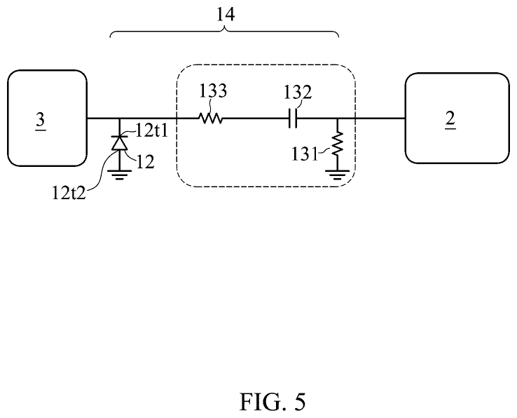

FIG. 5 is a circuit diagram of a circuit module (e.g., the circuit module 14) according to some embodiments of the present disclosure. The passive components 131, 132, and 133 may include an EOS circuit. The passive components 13 may include a first resistor (e.g., 133), a second resistor (e.g., 131), and a capacitor (e.g., 132). The first resistor and the second resistor may electrically connect to the capacitor. The second resistor may be connected to the ground and the first resistor may be connected to the electronic component 12. The electronic device 5 may be connected to a connector 2 and an electronic component 3. In some embodiments, the electronic component 12 may be configured to block a signal from the connector 2 to the electronic component 3 when a voltage difference between the first terminal 12t1 and the second terminal 12t2 of the electronic component 12 exceeds a predetermined value. The predetermined value may be a breakdown voltage of a Zener diode. The circuit module 14 may include a protection circuit configured to prevent the EOS-induced damage of a semiconductor die (e.g., 301 to 30N in FIG. 2).

Referring back to FIG. 4, the encapsulation layer 11 may cover and directly contact the passive components 131, 132, and 133 and the electronic component 12. The encapsulation layer 11 may be surrounded by the shield 17. The encapsulation layer 11 may be partially covered by the shield 17. The encapsulation layer 11 may include a top surface 11s1 and a lateral surface 11s3 connected to the top surface 11s1. The top surface 11s1 is substantially vertical to the lateral surface 11s3. The encapsulation layer 11 may include an epoxy resin including fillers, a molding compound (e.g., an epoxy molding compound or other molding compound), polyimide, a phenolic compound or material, a material including silicone dispersed therein, or a combination thereof. The encapsulation layer 11 may be electrically insulative.

The circuit module 14 may include a top surface 14s1 (e.g., the top surface 11s1) and a lateral surface 14s3 (e.g., the lateral surface 11s3). The shield 17 may be disposed at the top surface 14s1 and the lateral surface 14s3 of the circuit module 14. The shield 17 may be disposed over the top surface 14s1 and the lateral surface 14s3 of the circuit module 14. The shield 17 may include a first portion 171 disposed over the top surface 14s1 and a second portion 172 disposed over the lateral surface 14s3 of the circuit module 14. The first portion 171 may be connected to the second portion 172. The shield 17 may be formed by coating a conductive material on the top surface 14s1 and the lateral surface 14s3. The first portion 171 and the second portion 172 may conformally cover the circuit module 14 (or the encapsulation layer 11).

The carrier 10 may further include grounding pads 161 and 162 disposed at the surface 10s1 of the carrier 10. The grounding pads 161 and 162 may be connected to the pads 101p. The grounding pads 161 and 162 may be connected to the ground. The shield 17 (or the second portion 172) may be in contact with the grounding pads 161 and 162. The shield 17 may electrically connect to the grounding pads 161 and 162. The potential of the shield 17 may be connected to the ground. The shield 17 may be configured to shield physically and/or electromagnetically the circuit module 14 (i.e., the passive components 131, 132, and 133, and the electronic component 12) from an external environment.

In some cases, a module may be surrounded by a shield. The shield can electromagnetically shield the module from an external environment. However, a component of the module and the shield may induce an unwanted parasitic coupling therebetween and thus a high impedance may exist in a transmission path. In the present disclosure, the shield 17 has a selective shielding structure configured to reduce a parasitic coupling of the electronic device 5 (or the circuit module 14). The selective shielding structure of the shield 17 may include or define an opening 17h on the shield 17. The encapsulation layer 11 and the shield 17 may define the opening 17h. The opening 17h may expose a portion 14s1a of the top surface 14s1 (or the top surface 11s1) of the circuit module 14. The opening 17h may overlap or be faced toward one or more components (e.g., the passive component 132) of the circuit module 14. The location of the opening 17h may be determined based on the type of the components, the size of the components, and/or the distance between each of the components and the shield 17.

As shown in FIG. 4, the passive component 132 may have a size (or volume) larger than that of each of the passive components 131 and 133 and the electronic component 12. The relatively large size of the passive component 132 may indicate that the passive component 132 has higher impedance than the other components of the circuit module 14 and a tendency to induce a larger parasitic coupling with the shield 17. The location of the opening 17h may be determined to be aligned with the passive component 132.

In some embodiments, the passive component 132 may be spaced apart from the shield 17 with a distance 132d. The passive component 131 may be spaced apart from the shield 17 with a distance 131d. The distance 132d may be shorter than the distance 131d. The relatively short distance 132d may induce a larger parasitic coupling between the passive component 132 and the shield 17. The location of the opening 17h may be determined to be aligned with the passive component 132.

In some embodiments, the passive component 132 is a capacitor which can induce a parasitic coupling with the shield 17 larger than the resistors (e.g., the passive components 131 and 133). The location of the opening 17h may be determined to be aligned with the passive component 132.

The opening 17h may expose the portion 14s1a of the top surface 14s1 of the circuit module to reduce the parasitic coupling between the circuit module 14 and the shield 17. The opening 17h may overlap the portion 14s1a and a top surface 132s1 of the passive component 132 in a direction perpendicular to the top surface 14s1. The shield 17 may not cover the top surface 132s1 of the passive component 132. In some embodiments, a projecting area of the passive component 132 on the first surface 10s1 of the carrier 10 is free from overlapping a projecting area of the shield 17 on the first surface 10s1 of the carrier 10. The sidewalls of the opening 17h may be aligned with the terminals 132t1 and 132t2 of the passive component 132. The shield 17 provides an electromagnetic shielding effect for the circuit module 14.

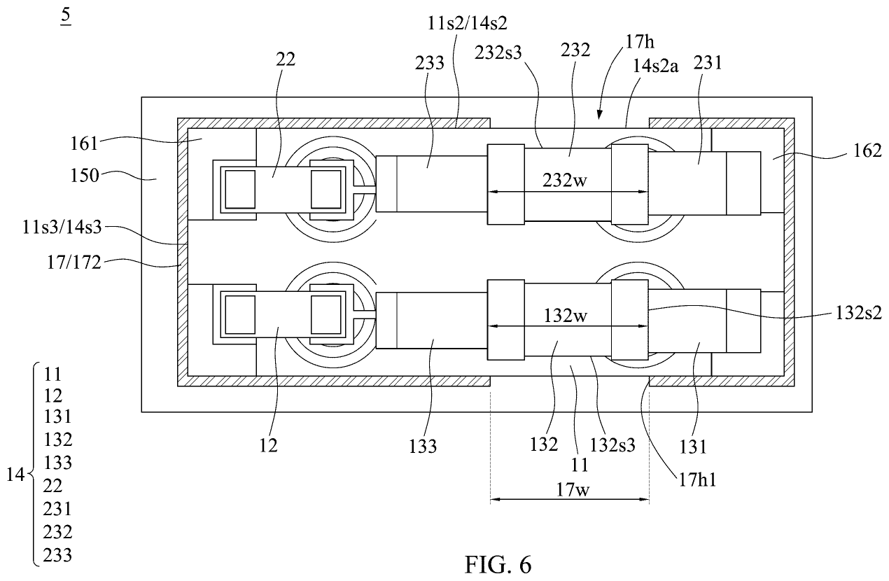

FIG. 6 is a top view of an electronic device (e.g., the electronic device 5) according to some embodiments of the present disclosure. As shown in FIG. 6, the circuit module 14 may be configured to transmit differential signals. The circuit module 14 may include a differential pair. The first group of the differential pair may include the electronic component 12 and the passive components 131, 132, and 133. The circuit module 14 may further include an electronic component 22 and a plurality of passive components 231, 232, and 233. The electronic component 22 may be similar to the electronic component 12. The passive components 231, 232, and 233 may be similar to the passive components 131, 132, and 133, respectively. The second group of the differential pair may include the electronic component 22 and the passive components 231, 232, and 233. In some embodiments, the first group may transmit a first signal and the second group may transmit a second signal. The first signal is differential to the second signal.

In some embodiments, the electronic component 22 and the passive components 231, 232, and 233 may be encapsulated, surrounded, or covered by the encapsulation layer 11. The electronic component 22 and the passive components 231, 232, and 233 may be surrounded by the shield 17.

The circuit module 14 may include a lateral side (or lateral surface) 14s2 connected to the lateral surface 14s3. The encapsulation layer 11 may have a lateral surface 11s2 (e.g., the lateral side 14s2) connected to the lateral surface 11s3. The shield 17 may be disposed at the lateral side 14s2 of the circuit module 14. The lateral side 14s2 of the circuit module 14 may be (partially) exposed by the opening 17h. A portion 14s2a of the lateral side 14s2 may be exposed by the opening 17h of the shield 17. The other portion of the lateral side 14s2 may be covered by the shield 17.

In some embodiments, the top surface 11s1 (FIG. 4) and the lateral surface 11s2 (FIG. 6) of the encapsulation layer 11 may be exposed by the opening 17h.

In some embodiments, a lateral surface 17h1 of the opening 17h may be substantially aligned with a lateral surface 132s2 of the passive component 132. The opening 17h may have a width 17w substantially the same as a width 232w of the passive component 232. The width 17w may be substantially the same as a width 132w of the passive component 132. The opening 17h may be faced toward the passive component 132. The passive component 132 may have a lateral surface 132s3 faced toward the opening 17h. The passive component 232 may have a lateral surface 232s3 faced toward the opening 17h. The lateral surface 132s3 of the passive component 132 may overlap the opening 17h in a direction perpendicular to the lateral surface 14s2 of the circuit module 14. The opening 17h may be faced toward the passive component 232. The passive component 232 may overlap the opening 17h. The lateral surface 232s3 of the passive component 232 may overlap the opening 17h in a direction perpendicular to the lateral surface 14s2 of the circuit module 14.

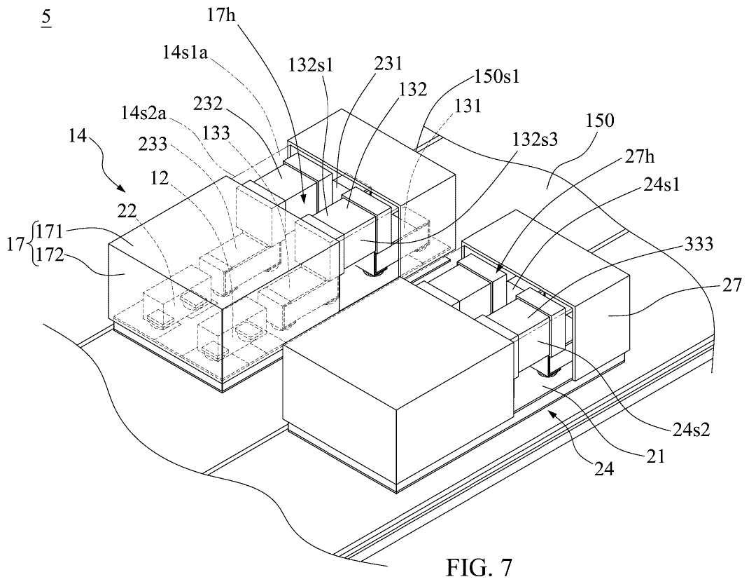

FIG. 7 is a three-dimensional view of an electronic device (e.g., the electronic device 5) according to some embodiments of the present disclosure.

The portion 14s1a of the top surface 14s1 and/or the portion 14s2a of the lateral side 14s2 of the circuit module 14 may be exposed by the opening 17h of the shield 17. The portion 14s1a of the top surface 14s1 and/or the portion 14s2a of the lateral side 14s2 of the circuit module 14 may overlap the opening 17h of the shield 17. The top surface 132s1 and/or the lateral surface 132s3 of the passive component 132 may be faced toward the opening 17h. The top surface 132s1 and/or the lateral surface 132s3 of the passive component 132 may overlap the opening 17h.

The electronic device 5 may further include a circuit module 24 disposed over the carrier 150. The circuit module 24 may be similar to the circuit module 14. The circuit module 24 may be arranged in parallel to the circuit module 14 in a direction along the long side 150s1 of the carrier 150. The electronic device 5 may further include a shield 27 surrounding the circuit module 24. The shield 27 may be spaced apart from the shield 17. The shield 27 may be disposed at a top surface 24s1 and/or a lateral side (or a lateral surface) 24s2 of the circuit module 24. The circuit module 24 may further include an encapsulation layer 21. The shield 27 may cover a portion of the encapsulation layer 21. The circuit module 14 and the shield 17 may be depicted in a perspective manner. The circuit module 24 and the shield 27 may be depicted in a non-perspective manner. The encapsulation layer 21 may be depicted in a perspective manner, such that one or more components of the circuit module 24 can be viewed.

The shield 27 may have a selective shielding structure configured to reduce a parasitic coupling between at least one of the components of the circuit module 24 and the shield 27. The selective shielding structure of the shield 27 may include or define an opening 27h. In some embodiments, the top surface 24s1 and/or the lateral side 24s2 of the circuit module 14 may be partially exposed by the opening 27h of the shield 27. The top surface 14s1 and/or the lateral side 14s2 of the circuit module 14 may partially overlap the opening 27h of the shield 27. In some embodiments, the circuit module 24 may include a passive component 333 faced toward the opening 27h. A top surface and a lateral surface of the passive component 333 may overlap or be faced toward the opening 27h. The opening 17h may be substantially aligned with the opening 27h in a direction perpendicular to the long side 150s1 of the carrier 150.

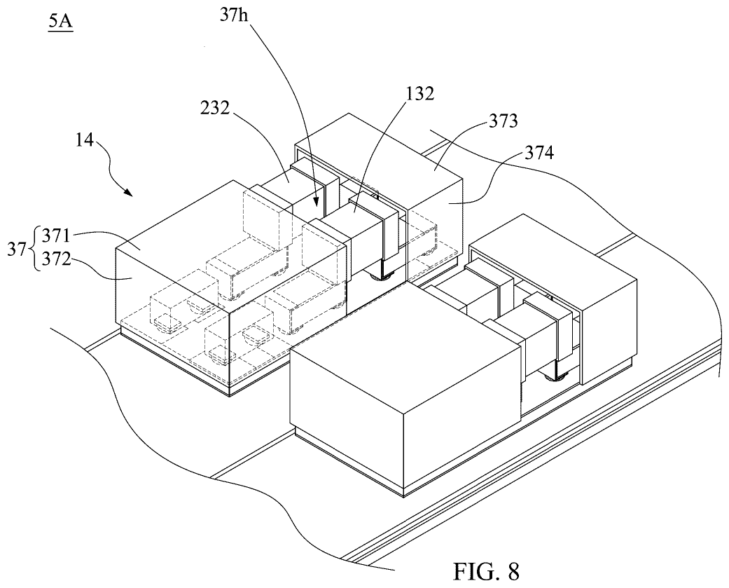

FIG. 8 is a three-dimensional view of an electronic device 5A according to some embodiments of the present disclosure. The electronic device 5A of FIG. 8 is similar to the electronic device 5 in FIGS. 4, 6, and 7. Therefore, some detailed descriptions may refer to corresponding preceding paragraphs and are not repeated hereinafter for conciseness, with differences therebetween as follows.

The electronic device 5A may include a shield 37, rather than the shield 17 of the electronic device 5 in FIG. 7. The shield 37 may be mounted on the carrier 10. The shield 37 may be shaped prior to being mounted on the carrier 10. The shield 37 may include a shield can. In some embodiments, the circuit module 14 may not include an encapsulation layer.

The shield 37 may include or define an opening 37h for exposing the passive component 132. The shield 37 may include a portion 371 disposed directly above the electronic component 12 and the passive component 133. The shield 37 may include a portion 372 connected to the portion 371 and for electromagnetically isolating the electronic component 12 and the passive component 133 from the external environment. The shield 37 may include a portion 373 disposed directly above the passive component 131. The shield 37 may include a portion 374 connected to the portion 373 and for electromagnetically isolating the passive component 131 from the external environment.

In some embodiments, the circuit module 24 may be surrounded by a shield can similar to or the same as the shield 37.

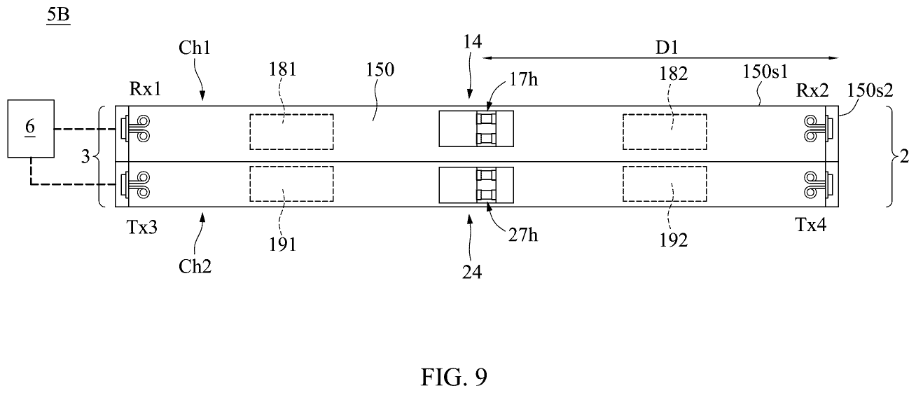

FIG. 9 is a top view of an electronic device 5B according to some embodiments of the present disclosure. The electronic device 5B of FIG. 9 is similar to the electronic device 5 in FIGS. 4, 6, and 7 or the electronic device 5A in FIG. 8. Therefore, some detailed descriptions may refer to corresponding preceding paragraphs and are not repeated hereinafter for conciseness, with differences therebetween as follows.

As shown in FIG. 9, the carrier 150 of the electronic device 5B may be connected to the connector 2 at a short side 150s2. The carrier 150 of the electronic device 5B may be connected to the electronic component 3 at an opposite short side 150s2. In some embodiments, the electronic component 3 may be electrically connected to a device 6. The device 6 may be one of the semiconductor dies 301, . . . , 30N of FIG. 2. The device 6 may include a power management IC, radio frequency IC, driver IC, controller IC, or the like. The electronic component 3 may be configured to synchronize a first signal transmitted from the connector 2 to the device 6 and a second signal transmitted from the device 6 to the connector 2.

In some embodiments, the electronic device 5B may further include a circuit module 181 disposed between the circuit module 14 and the electronic component 3. The electronic device 5B may further include a circuit module 182 disposed between the circuit module 14 and the connector 2. The circuit module 181 and the circuit module 182 may be electrically connected to the circuit module 14 via the carrier 150. The circuit module 181 and the circuit module 182 may include a filter, a voltage adjusting circuit, an attenuation circuit, or an electrical load.

In some embodiments, the electronic device 5B may further include a circuit module 191 disposed between the circuit module 24 and the electronic component 3. The electronic device 5B may further include a circuit module 192 disposed between the circuit module 24 and the connector 2. The circuit module 191 and the circuit module 192 may be electrically connected to the circuit module 24 via the carrier 150. The circuit module 191 and the circuit module 192 may include a filter, a voltage adjusting circuit, an attenuation circuit, or an electrical load.

As shown in FIG. 9, the electronic device 5B may include a first channel Ch1 and a second channel Ch2. The first channel Ch1 may be configured to receive signals from the connecter 2. The first channel Ch1 may be a receiver channel (Rx channel). The first channel may include a first terminal Rx1 and a second terminal Rx2. The second channel Ch2 may be configured to transmit signals from the electronic component 3 to the connecter 2. The second channel Ch2 may be a transmitter channel (Tx channel). The second channel Ch2 may include a third terminal Tx3 and a fourth terminal Tx4.

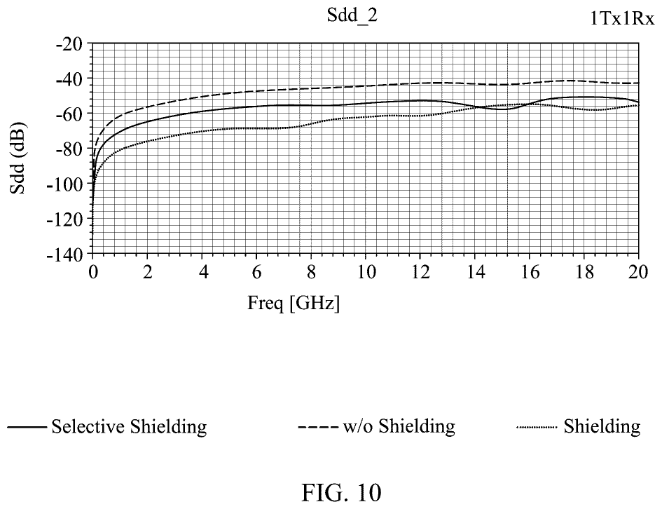

FIG. 10 is a plot for a near-end-cross-talk of terminals Tx3 and Rx1 in an electronic device according to some embodiments of the present disclosure. FIG. 10 shows the near-end-cross-talk of the terminals Tx3 and Rx1 in three different conditions: (1) “Selective Shielding” represented by a solid line; (2) “w/o Shielding” represented by a dashed line; and (3) “Shielding” represented by a dotted line. Condition (1) represents the electronic device 5B of FIG. 9. Condition (2) represents a similar electronic device without shield. Condition (3) represents a similar electronic device that is completely isolated by a shield (e.g., no opening). As shown in FIG. 10, the near-end-cross-talk of the “Selective Shielding” is better than that of “w/o Shielding,” while worse than that of “Shielding.” In other words, the signals at the terminal Tx3 of the electronic device 5B may be more sensitive to the signals at the terminal Rx1 than a similar electronic device with “Shielding.” The signals at the terminal Tx3 of the electronic device 5B may be less sensitive to the signals at the terminal Rx1 than a similar electronic device with “w/o Shielding.”

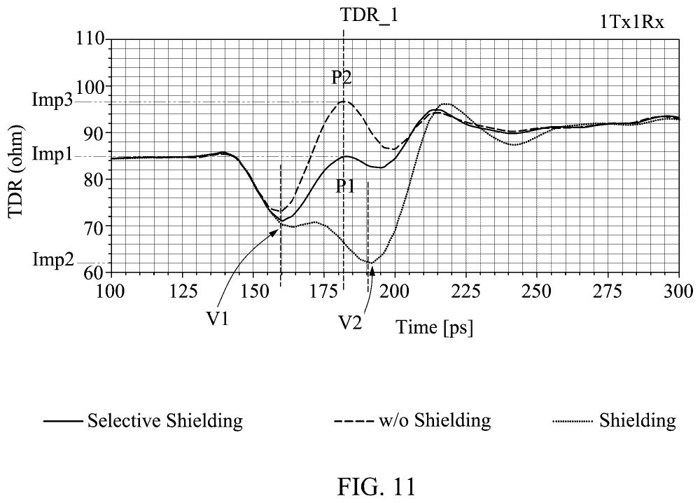

FIG. 11 is a Time Domain Reflectometry (TDR) plot of an electronic device according to some embodiments of the present disclosure. FIG. 11 shows the TDR characteristics in three different conditions: (1) “Selective Shielding” represented by a solid line; (2) “w/o Shielding” represented by a dashed line; and (3) “Shielding” represented by a dotted line. Condition (1) represents the electronic device 5B of FIG. 9. Condition (2) represents a similar electronic device without shield. Condition (3) represents a similar electronic device that is completely isolated by a shield (e.g., no opening). The TDR characteristics show the variation of the impedance values along the transmission path (or the first channel Ch1 or the second channel Ch2). The measurement of the TDR characteristics can be implemented by providing an incident signal at a terminal (e.g., the terminal Rx2 or Tx4) of the transmission path and receiving its reflections. An impedance mismatch (or discontinuity) in the transmission path can reflect a part of the incident signal. If the time value of the x axis multiplies the light speed in the transmission path, the distance between the terminal and a specific component can be determined. An impedance value at a point in the transmission path can be calculated by comparing the magnitude of the incident signal and the reflection(s).

The TDR characteristic of the “Selective Shielding” represents the electronic device 5B of FIG. 9. In some embodiments, the first channel Ch1 or the second channel Ch2 of the electronic device 5B may have the TDR characteristic of the “Selective Shielding.” The TDR characteristic of the “Selective Shielding” may have a turning point P1. The turning point P1 may correspond to a location of the opening 17h with respect to the long side 150s1 of the carrier 150 in FIG. 9. A distance D1 between the connector 2 (or the terminal Rx2) and the opening 17h represents the location of the opening 17h. When a time value of the turning point P1 multiplies the light speed in the electronic device 5B, the distance D1 can be determined. In some embodiments, the distance D1 may equal to ½*time value*light speed. In some embodiments, the turning point P1 may correspond to the location of the passive component 132. The turning point P1 may represent a first parasitic coupling among the passive component 132, the shield 17, and an external environment. The first parasitic coupling may induce a parasitic inductance, if the passive component 132 includes a capacitor. An impedance value Imp1 of the turning point P1 may be the value of the parasitic inductance. The first parasitic coupling may induce a parasitic capacitance, if the passive component 132 includes an inductor.

The TDR characteristic of the “Selective Shielding” may have a turning point V1. The turning point V1 may correspond to the location of the electronic component 12 with respect to the long side 150s1 of the carrier 150 in FIG. 9. The electronic component 12 may be a diode which can be referred to as a capacitor. The turning point V1 may represent a second parasitic coupling between the electronic component 12 and the shield 17. The second parasitic coupling may induce a parasitic capacitance.

In some embodiments, the TDR characteristic of the “Shielding” may have a turning point V2. The turning point V2 may have an impedance value Imp2. The impedance value Imp2 may be a parasitic capacitance between a passive component and a shield. In some embodiments, the TDR characteristic of the “w/o Shielding” may have a turning point P2. The turning point P2 may have an impedance value Imp3. The impedance value Imp3 may be a parasitic inductance between a passive component and an external environment.

The impedance value Imp1 of the turning point P1 is higher than the impedance value Imp2 of the turning point V2. The impedance value Imp1 of the turning point P1 is lower than the impedance value Imp3 of the turning point P2.

The less the variation in the TDR characteristic, the better the transmission efficiency of an electronic device. The TDR characteristic of “Selective Shielding” has less variation compared to both “w/o Shielding” and “Shielding.” For example, the impedance value Imp1 of the turning point P1 is moderate compared to the impedance values Imp2 and Imp3. The selective shielding structure (e.g., the opening 17h) of the shield 17 is configured to reduce the parasitic coupling between the passive component 132 and the shield 17. The transmission efficiency of the electronic device 5B can be improved.

The selective shielding may reduce parasitic coupling between the circuit module 14 and the shield 17, while the near-end cross talk between the adjacent terminals Tx3 and Rx1 may be greater, as shown in FIG. 10. There is a trade-off between reducing parasitic coupling and suppressing near-end cross talk. The location of the opening 17h and its size/shape can be determined based on the measurement data of the near-end-cross-talk plot and the TDR plot.

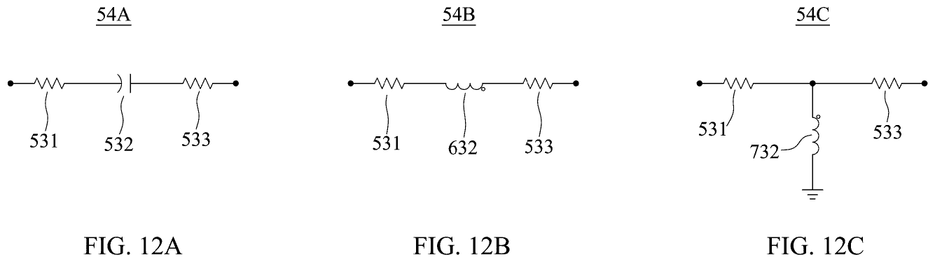

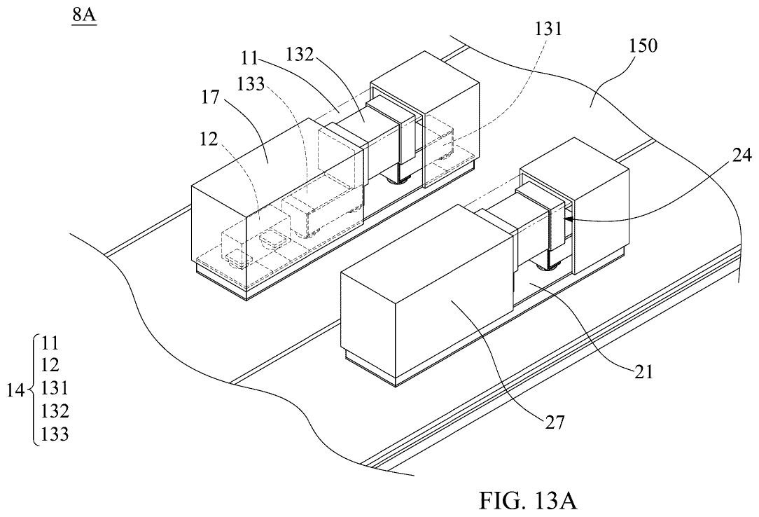

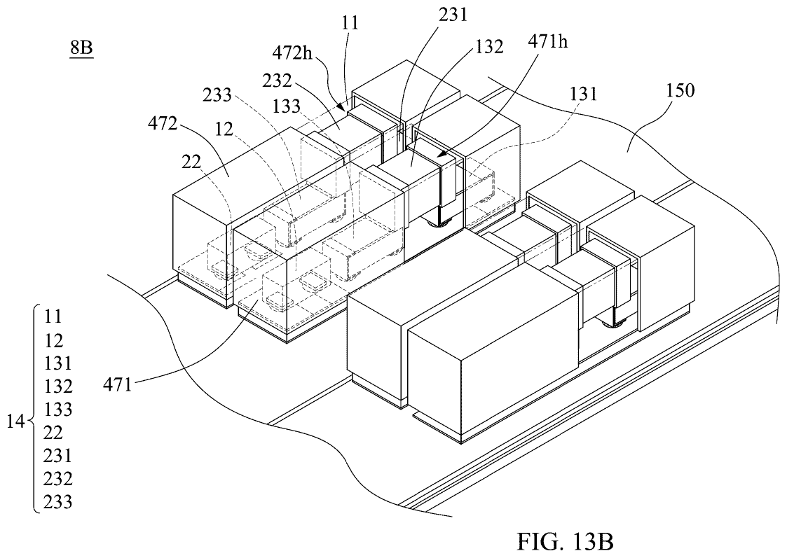

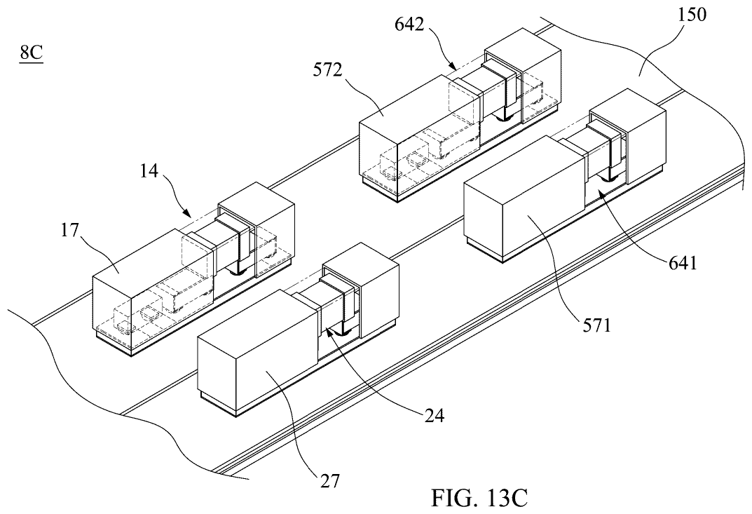

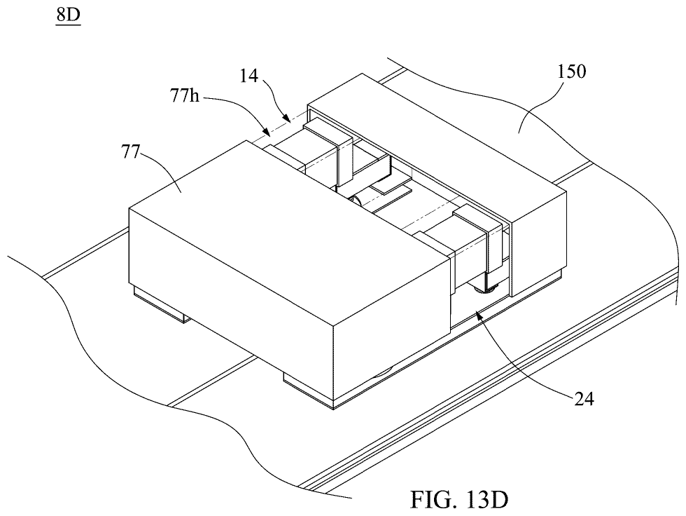

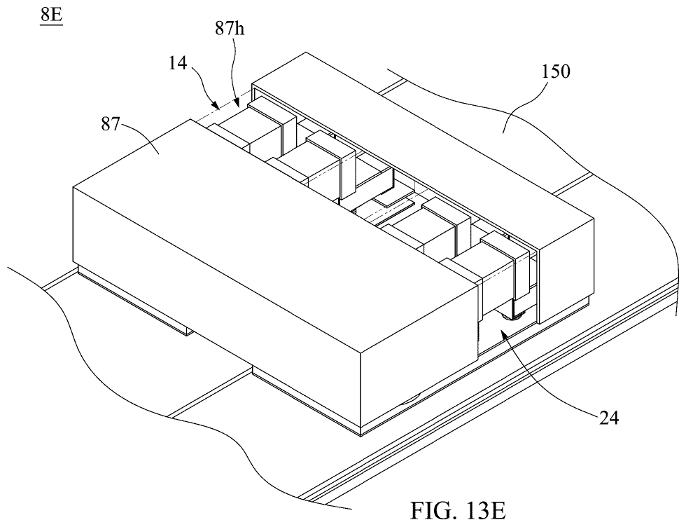

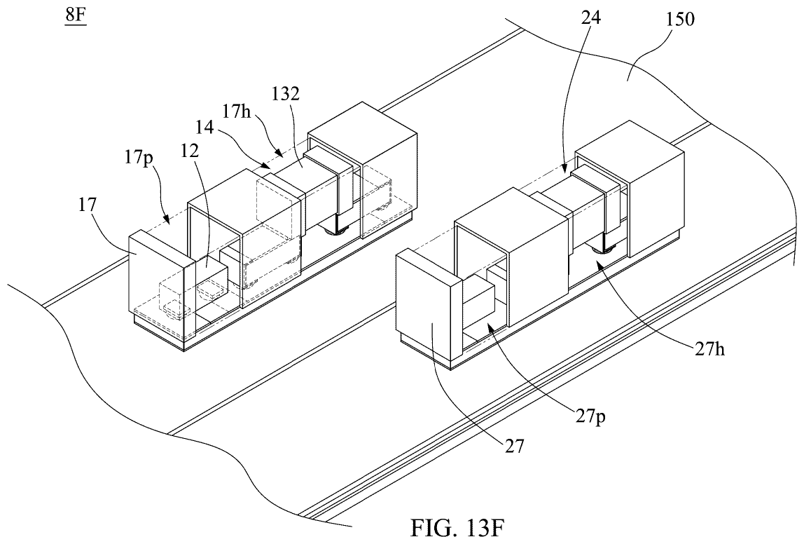

FIGS. 12A, 12B, and 13C each represent a circuit diagram of a circuit module according to some embodiments of the present disclosure. Each of the circuit modules of FIGS. 12A, 12B, and 12C can be applied to a circuit module in the electronic devices 5, 5A, and 5B.

As shown in FIG. 12A, a circuit module 54A may include passive components 531, 532, and 533. The passive component 531 is electrically connected to the passive component 532 in series. The passive component 532 is electrically connected to the passive component 533 in series. Each of the passive components 531 and 533 may be a resistor. The passive component 532 may be a capacitor.

As shown in FIG. 12B, a circuit module 54B may include passive components 531, 632, and 533. The passive component 531 is electrically connected to the passive component 632 in series. The passive component 632 is electrically connected to the passive component 533 in series. The passive component 632 may be an inductor.

As shown in FIG. 12C, a circuit module 54B may include passive components 531, 732, and 533. The passive component 531 is electrically connected to the passive component 533 in series. The passive component 732 is electrically connected to the passive components 531 and 533 at the same node. The passive component 732 may be connected to the ground. The passive component 732 may be an inductor.

FIG. 13A is a three-dimensional view of an electronic device 8A according to some embodiments of the present disclosure. The electronic device 8A of FIG. 13A is similar to the electronic device 5 in FIG. 7. Therefore, some detailed descriptions may refer to corresponding preceding paragraphs and are not repeated hereinafter for conciseness, with differences therebetween as follows.

As shown in FIG. 13A, the circuit module 14 may have no differential pair. The circuit module 14 may include the electronic component 12 and the passive components 131, 132, and 133 for transmitting a single signal.

FIG. 13B is a three-dimensional view of an electronic device 8B according to some embodiments of the present disclosure. The electronic device 8B of FIG. 13B is similar to the electronic device 5 in FIG. 7. Therefore, some detailed descriptions may refer to corresponding preceding paragraphs and are not repeated hereinafter for conciseness, with differences therebetween as follows.

As shown in FIG. 13B, each group of the differential pair of the circuit module 14 is surrounded by a respective shield. The first group (i.e., the electronic component 12 and the passive components 131, 132, and 133) may be surrounded by a shield 471 and the second group (i.e., the electronic component 22 and the passive components 231, 232, and 233) may be surrounded by a shield 472. The shield 471 may be spaced apart from the shield 472. The passive component 132 may be exposed by an opening 471h of the shield 471. The passive component 232 may be exposed by an opening 472h of the shield 472.

FIG. 13C is a three-dimensional view of an electronic device 8C according to some embodiments of the present disclosure. The electronic device 8C of FIG. 13C is similar to the electronic device 5 in FIG. 7. Therefore, some detailed descriptions may refer to corresponding preceding paragraphs and are not repeated hereinafter for conciseness, with differences therebetween as follows.

As shown in FIG. 13C, further circuit modules 641 and 642 are disposed over the carrier 150. The further circuit module 642 and the circuit module 14 are on the same channel. The further circuit module 641 and the circuit module 24 are on the same channel. The further circuit modules 641 and 642 are surrounded by shields 571 and 572, respectively. The shields 571 and 572 may each include or define an opening for exposing at least one component of the further circuit modules 641 and 642.

FIG. 13D is a three-dimensional view of an electronic device 8D according to some embodiments of the present disclosure. The electronic device 8D of FIG. 13D is similar to the electronic device 8A in FIG. 13A. Therefore, some detailed descriptions may refer to corresponding preceding paragraphs and are not repeated hereinafter for conciseness, with differences therebetween as follows.

As shown in FIG. 13D, the circuit module 14 and the circuit module 24 are covered by a shield 77. In some embodiments, the shield 77 may include an opening 77h. The opening 77h may expose a portion of the circuit module 14 and the circuit module 24. The opening 77h may overlap a lateral side of the circuit module 14 and a lateral side of the circuit module 24.

FIG. 13E is a three-dimensional view of an electronic device 8E according to some embodiments of the present disclosure. The electronic device 8E of FIG. 13E is similar to the electronic device 5 in FIG. 7. Therefore, some detailed descriptions may refer to corresponding preceding paragraphs and are not repeated hereinafter for conciseness, with differences therebetween as follows.

As shown in FIG. 13E, the circuit module 14 and the circuit module 24 are covered by a shield 87. In some embodiments, the shield 87 may include an opening 87h. The opening 87h may expose a portion of the circuit module 14 and the circuit module 24. The opening 87h may overlap a lateral side of the circuit module 14 and a lateral side of the circuit module 24.

FIG. 13F is a three-dimensional view of an electronic device 8F according to some embodiments of the present disclosure. The electronic device 8F of FIG. 13F is similar to the electronic device 5 in FIG. 7. Therefore, some detailed descriptions may refer to corresponding preceding paragraphs and are not repeated hereinafter for conciseness, with differences therebetween as follows.

As shown in FIG. 13F, the shield 17 further includes or defines an opening 17p spaced apart from the opening 17h. The opening 17p may expose a portion of the circuit module 14. The opening 17p may be substantially aligned with the electronic component 12. The electronic component 12 may be faced toward the opening 17p. The opening 17p may be configured to reduce a parasitic coupling between electronic component 12 and the shield 17.

In some embodiments, the shield 27 further includes or defines an opening 27p spaced apart from the opening 27h. The opening 27p may expose a portion of the circuit module 24. The opening 27p may be substantially aligned with an electronic component of the circuit module 24. The electronic component may be faced toward the opening 27p. The opening 27p may be configured to reduce a parasitic coupling between the electronic component and the shield 27. The opening 17h is misaligned with the opening 27h in a direction perpendicular to the long side 150s1 of the carrier 150. The opening 17p is misaligned with the opening 27p in a direction perpendicular to the long side 150s1 of the carrier 150.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first circuit module; and
a first shield disposed at a lateral side of the first circuit module and comprising a first opening configured to reduce a parasitic coupling of the first circuit module and the first shield.

2. The electronic device of claim 1, wherein the first circuit module includes a capacitor, and the first opening is configured to reduce a parasitic capacitance between the capacitor and the first shield.

3. The electronic device of claim 1, wherein the first circuit module is configured to clamp a voltage of the electronic device.

4. The electronic device of claim 1, further comprising a second circuit module and a second shield disposed at a lateral side of the second circuit module, wherein the second shield comprises a second opening configured to reduce a parasitic coupling of the second circuit module and the second shield.

5. The electronic device of claim 4, further comprising a carrier for supporting the first circuit module and the second circuit module, wherein the first opening is substantially aligned with the second opening in a direction perpendicular to a long side of the carrier.

6. The electronic device of claim 4, further comprising a carrier for supporting the first circuit module and the second circuit module, wherein the first opening is misaligned with the second opening in a direction perpendicular to a long side of the carrier.

7. The electronic device of claim 4, wherein the first shield is spaced apart from the second shield.

8. An electronic device, comprising:
a circuit module comprising a first passive component; and
a shield disposed at a lateral side of the circuit module and comprising an opening faced toward the first passive component.

9. The electronic device of claim 8, wherein the circuit module further comprises a second passive component, and the first passive component has a first volume larger than a second volume of the second passive component.

10. The electronic device of claim 8, wherein the circuit module further comprises a second passive component, and a first distance between the shield and the first passive component is shorter than a second distance between the shield and the second passive component.

11. The electronic device of claim 10, further comprising a carrier for supporting the circuit module, wherein the first passive component is higher than the second passive component with respect to the carrier.

12. The electronic device of claim 8, wherein a lateral surface of the opening is substantially aligned with a lateral surface of the first passive component.

13. The electronic device of claim 8, wherein the opening overlaps a top surface and a lateral surface of the first passive component.

14. The electronic device of claim 8, wherein the circuit module further comprises an encapsulation layer encapsulating the first passive component, wherein the encapsulation layer and the shield define the opening.

15. The electronic device of claim 14, wherein the encapsulation layer has a top surface and a lateral surface, wherein the opening exposes the top surface and the lateral surface.

16. The electronic device of claim 8, wherein the circuit module further comprises a second passive component, wherein the second passive component overlaps the opening.

17. The electronic device of claim 16, wherein the first passive component is configured to transmit a first signal and the second passive component is configured to transmit a second signal, wherein the first signal is differential to the second signal.

18. An electronic device, comprising:
a carrier having a long side;
a circuit module disposed over the carrier; and
a shield surrounding the circuit module and comprising an opening;
wherein the electronic device has a Time Domain Reflectometry (TDR) characteristic, and
wherein the TDR characteristic has a first turning point corresponding to a location of the opening with respect to the long side of the carrier.

19. The electronic device of claim 18, wherein the circuit module comprises a first passive component exposed by the opening, and wherein the first turning point of the TDR characteristic represents a parasitic coupling among the first passive component, the shield, and an external environment.

20. The electronic device of claim 18, wherein the first turning point has a first impedance value that is higher than a second impedance value of a second turning point of a TDR characteristic of an external electronic device that is completely isolated from an external environment.
